(19) United States
(12) Patent Application Publication
(10) Pub. No.: US 2024/0429331 A1
(43) Pub. Date: Dec. 26, 2024

(54) SEMICONDUCTOR LIGHT RECEIVING ELEMENT

(71) Applicant: Dexerials Corporation, Tochigi (JP)

(72) Inventors: Takatomo ISOMURA, Tochigi (JP); Etsuji OMURA, Tochigi (JP)

(73) Assignee: Dexerials Corporation, Tochigi (JP)

(21) Appl. No.: 18/822,267

(22) Filed: Sep. 1, 2024

Related U.S. Application Data
(63) Continuation of application No. PCT/JP2022/009420, filed on Mar. 4, 2022.

(51) Int. Cl. H01L 31/0236; H01L 31/0216; H01L 31/0304; H01L 31/105

(52) U.S. Cl. CPC H01L 31/02366; H01L 31/02161; H01L 31/03046; H01L 31/105

(57) ABSTRACT

In a semiconductor light receiving element having a light receiving part having a light absorption layer on a first surface side of a semiconductor substrate that is transparent to light with wavelengths in the infrared region for optical communication, a second surface side opposite to the first surface is provided with an inclined portion inclined at a predetermined angle with respect to the first surface in a region where transmitted light that has passed through the light absorption layer of incident light that has entered the light receiving part from the opposite side to the semiconductor substrate reaches, and a rough surface having irregularities with a height equal to or greater than the wavelength of the transmitted light is formed on the inclined portion, thereby reducing re-entry of the transmitted light into the light receiving part.

### CROSS-REFERENCE TO RELATED APPLICATION

This application is a continuation of the International PCT application serial no. PCT/JP2022/009420, filed on Mar. 4, 2022. The entirety of the above-mentioned patent application is hereby incorporated by reference herein and made a part of this specification.

### BACKGROUND

### 1. Technical Field

The present invention relates to a semiconductor light receiving element for receiving infrared light used in optical measurement and optical communication, and more particularly to a semiconductor light receiving element having improved falling response characteristics after receiving an optical pulse.

### 2. Related Art

Optical time domain reflectometers (OTDRs) have been widely used to measure the loss state and defect location of optical fiber cables used in optical communication. This optical time domain reflectometer inputs pulsed light with a pulse width of, for example, about 100 ns into one end of an installed optical fiber cable, and receives backscattered light that returns to the input side out of the Rayleigh scattered light that is generated when this pulsed light propagates through the optical fiber cable. It then measures the loss based on the amount (intensity) of the backscattered light, and measures the distance from the optical time domain reflectometer based on the time from inputting the pulsed light to receiving the backscattered light.

At the connection point where the optical pulse tester is connected to one end of the optical fiber cable under test, Fresnel reflection is unavoidable when pulsed light enters the optical fiber cable. Therefore, when pulse light is emitted from the optical pulse tester, the Fresnel reflected light at this connection point is received first by the optical pulse tester, and then the backscattered light is received.

The light intensity of this backscattered light is extremely low compared to Fresnel reflected light. Therefore, the light receiving element of the optical pulse tester cannot detect the backscattered light until the time it receives the Fresnel reflected light, which corresponds to the pulse width of the pulsed light, and the response time (fall time) from when the Fresnel reflected light is no longer received until it becomes possible to detect the backscattered light, have elapsed. As a result, even if a defect exists within the distance of the light traveling back and forth from the optical pulse tester, which corresponds to the time when the backscattered light cannot be detected, a dead zone occurs in which the defect cannot be detected.

In order to reduce the dead zone, it is required to shorten the fall time of the light receiving element. For example, as shown in Patent Document 1, a semiconductor light receiving element is known in which the light transmitted through the first light absorbing layer of the light receiving section is absorbed by the second light absorbing layer, thereby reducing the light that re-enters the first light absorbing layer, in order to shorten the fall time of the light receiving element. Since the light that has transmitted through the first light absorbing layer is reflected and the amount of light that re-enters the first light absorbing layer is reduced, the photocurrent decreases rapidly when the light has finished transmitting through the first light absorbing layer, and the fall time is shortened.

### PRIOR ART DOCUMENTS

### Patent Documents

Patent Document #1: Japanese Unexamined Patent Application Publication No. Hei 8-8456

### SUMMARY

The semiconductor light receiving element of Patent Document #1 has a first light absorbing layer for converting incident light into a photocurrent (electrical signal), and a second light absorbing layer for absorbing light that has passed through the first light absorbing layer to prevent it from re-entering the first light absorbing layer. This makes the structure complicated, and since it is necessary to separately form the two light absorbing layers, which are not easy to form because they are grown by crystals, there is a problem that the manufacturing cost increases.

An object of the present invention is to provide a semiconductor light receiving element configured so that light transmitted through a light absorbing layer in a light receiving portion is not re-entered into the light receiving portion.

The semiconductor light receiving element of the present invention is a semiconductor light receiving element including a light receiving portion having a light absorption layer on a first surface side of a semiconductor substrate transparent to light having a wavelength in an infrared region for optical communication; wherein a second surface side of the semiconductor substrate opposite to the first surface includes an inclined portion inclined at a predetermined angle with respect to the first surface in a region where transmitted light that is transmitted through the light absorption layer out of incident light that is incident on the light receiving portion from an opposite side to the semiconductor substrate reaches the second surface side of the semiconductor substrate, and a rough surface having irregularities with a height equal to or greater than the wavelength of the transmitted light is formed on the inclined portion.

According to the above configuration, the semiconductor light receiving element includes a light receiving section having a light absorbing layer on the first surface side of a semiconductor substrate that transmits light with wavelengths in the infrared light region, and light is incident on this light receiving section from the opposite side to the semiconductor substrate. The second surface side of the semiconductor substrate, which is opposite to the first surface, includes an inclined portion inclined at a predetermined angle with respect to the first surface of the semiconductor substrate in a region where the transmitted light that has passed through the light absorbing layer of the light receiving section reaches. Since the inclined portion has a rough surface having irregularities with a height equal to or greater than the wavelength of the transmitted light, most of the transmitted light that reaches the inclined portion goes out to the outside of the semiconductor substrate without being reflected. In addition, since the inclined portion is inclined at a predetermined angle with respect to the first surface of the semiconductor substrate, it is possible to prevent the light reflected by the inclined portion out of the transmitted light from being reflected toward the light receiving section. Therefore, it is possible to reduce the re-entry of the transmitted light into the light receiving section, thereby shortening the fall time of the semiconductor light receiving element.

In a first applicable aspect of the present invention, the inclined portion is formed by a V-shaped groove recessed into the semiconductor substrate from the second surface toward the first surface.

According to the above-mentioned configuration, the inclined portion is formed by a V-shaped groove, and the rough surface formed in the V-shaped groove is protected from damage due to collision or friction with an external object, thereby making it easier to handle the semiconductor light receiving element.

In a second applicable aspect of the present invention, the first surface of the semiconductor substrate is a (100) surface of the semiconductor substrate, and the inclined portion is formed on a (111) surface of the semiconductor substrate.

According to the above configuration, the predetermined angle of the inclined portion with respect to the first surface of the semiconductor substrate is determined so that the transmitted light is reflected by the inclined portion toward the second surface of the semiconductor substrate, thereby preventing the transmitted light that has passed through the light absorption layer of the light receiving portion from being reflected by the inclined portion so as to return to the light receiving portion.

In a third applicable aspect of the present invention, a rough surface having irregularities with a height equal to or greater than the wavelength of the transmitted light is formed on the second surface of the semiconductor substrate.

According to the above configuration, when a portion of the transmitted light that has passed through the light absorbing layer of the light receiving section is reflected by the inclined portion and reaches the second surface of the semiconductor substrate, the reflection of the light on the second surface of the semiconductor substrate can be reduced. Therefore, the re-entry of the transmitted light that has passed through the light absorbing layer of the light receiving section into the light receiving section can be further reduced.

According to the semiconductor light receiving element of the present invention, it is possible to prevent light that has passed through the light absorption layer of the light receiving portion from re-entering the light receiving portion.

### BRIEF DESCRIPTION OF THE DRAWINGS

FIG. 1 is a perspective view of a semiconductor light receiving element according to an embodiment of the present invention;

FIG. 2 is a plan view of the semiconductor light receiving element of FIG. 1 as viewed from the light incident side;

FIG. 3 is a cross-sectional view taken along line III-III in FIG. 2;

FIG. 4 is an explanatory diagram of sandblasting processing;

FIG. 5 is a cross-sectional model diagram of a microtexture formed on an inclined surface of a semiconductor substrate;

FIG. 6 is a graph showing reflectance due to microtexture;

FIG. 7 is a diagram illustrating an example of a light beam incident on a light receiving unit;

FIG. 8 is a diagram illustrating an example of light rays when the second surface of the semiconductor substrate is also formed to be a rough surface; and

FIG. 9 is a diagram illustrating a modified example of a semiconductor element.

### DESCRIPTION OF EXEMPLARY EMBODIMENTS

Hereinafter, the mode for carrying out the present invention will be described based on examples.

The semiconductor light receiving element 1 includes, for example, a PIN photodiode or an avalanche photodiode that receives incident light in the infrared light region (wavelength region of 1100 to 1600 nm) for optical communications. Here, an example of the semiconductor light receiving element 1 including a PIN photodiode will be described.

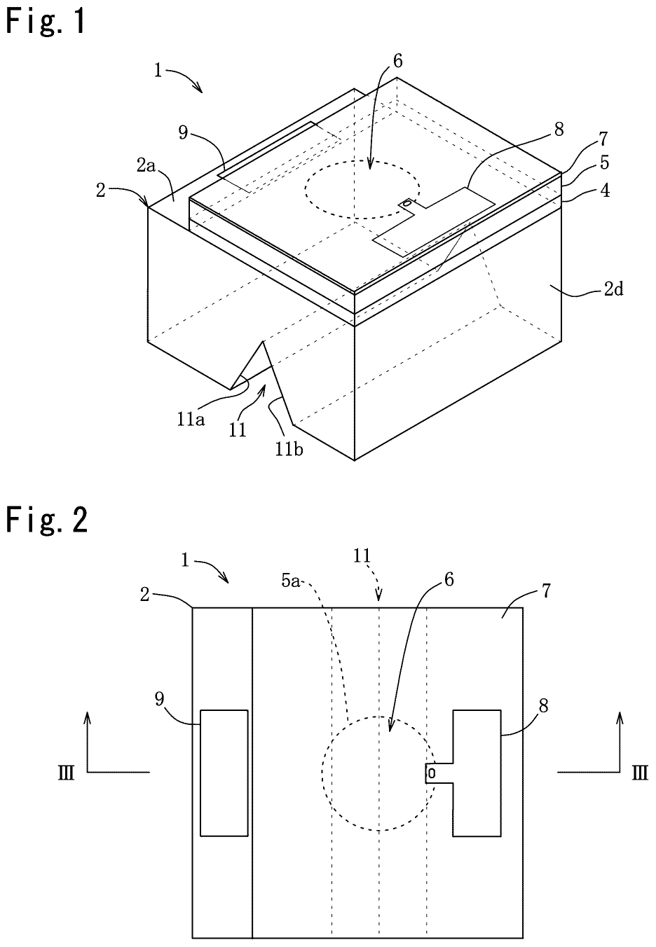

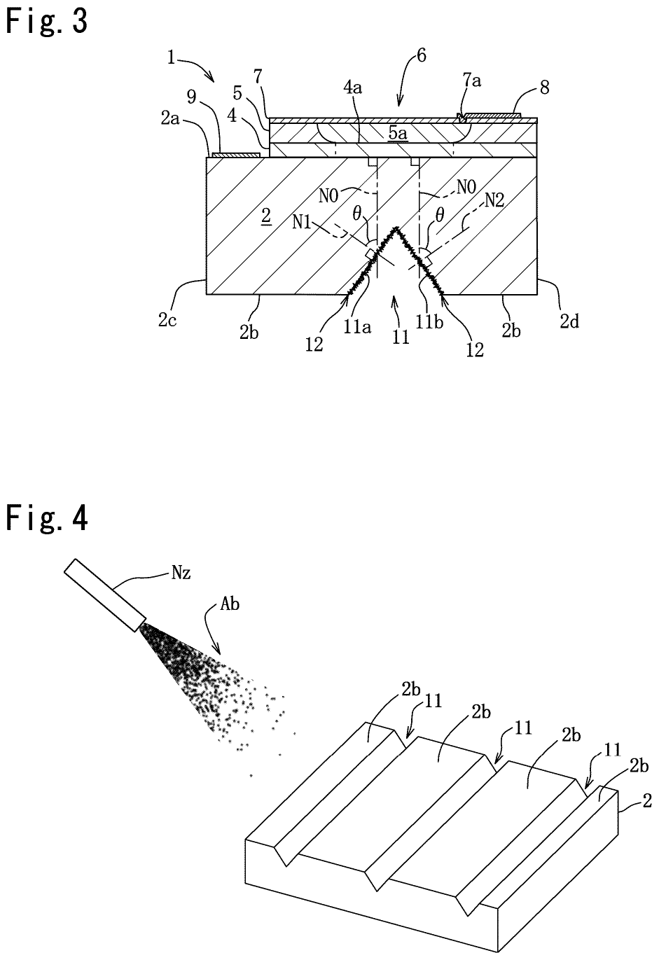

As shown in FIGS. 1 to 3, the semiconductor light receiving element 1 has, for example, an n-InP substrate as a single crystal semiconductor substrate 2 that is transparent to incident light with a wavelength in the infrared light region for optical communications. A first surface 2a (front surface) of this semiconductor substrate 2 is the (100) surface of the semiconductor substrate 2. On the first surface 2a side, for example, an InGaAs layer is formed as a light absorption layer 4 that absorbs incident light, and an n-InP layer is formed as a semiconductor layer 5.

The semiconductor layer 5 has a p-type diffusion region 5a selectively doped with, for example, Zn. The region of the light absorbing layer 4 in contact with the p-type diffusion region 5a is the light absorbing region 4a, and the p-type diffusion region 5a, the light absorbing region 4a, and the semiconductor substrate 2 form a PIN photodiode that is the light receiving section 6. The thicknesses of the semiconductor layer 5 and the light absorbing layer 4 are each appropriately set and are formed to a thickness of, for example, 0.5 to 5 μm.

The surface of the semiconductor layer 5 is covered with a protective film 7 (e.g., a SiN film, a SiON film, etc.) having an opening 7a communicating with the p-type diffusion region 5a. The protective film 7 may have an anti-reflection function for light incident on the light receiving section 6. An anode electrode 8 is formed, which is connected to the p-type diffusion region 5a through the opening 7a of the protective film 7. The size and shape of the p-type diffusion region 5a are each appropriately set, and is formed into a circle with a diameter of, for example, 10 to 200 μm.

A cathode electrode 9 connected to the first surface 2a of the semiconductor substrate 2 is formed in an exposed portion of the semiconductor substrate 2. The anode electrode 8 and the cathode electrode 9 are formed by selectively depositing a metal film containing, for example, chromium or gold. The photocurrent photoelectrically converted in the light receiving unit 6 is output to the outside via the anode electrode 8 and the cathode electrode 9.

Light is incident on the light receiving section 6 from the side opposite to the semiconductor substrate 2. The second surface 2b side opposite to the first surface 2a of the semiconductor substrate 2 is provided with an inclined portion 11 in a region where transmitted light that has entered the light receiving section 6 and passed through the light absorbing layer 4 (light absorbing region 4a) reaches.

The inclined portion 11 is formed by a groove having a V-shaped cross section recessed from the second surface 2b side toward the first surface 2a side of the semiconductor substrate 2, and has two inclined surfaces 11a, 11b. These inclined surfaces 11a, 11b are formed such that normals N1, N2 of the inclined surfaces 11a, 11b intersect with the normal N0 of the first surface 2a at a predetermined angle θ that is greater than 45°.

The V-shaped groove is formed by known anisotropic etching using, for example, a bromine-methanol solution as a known etching solution whose etching rate depends on the crystal plane orientation. Specifically, an etching mask layer is formed on the second surface 2b of the semiconductor substrate 2, and anisotropic etching is performed from the exposed portion of the second surface 2b to expose the (111) surface of the semiconductor substrate 2, which has a slower etching rate. This forms two inclined surfaces 11a and 11b, which are the (111) surfaces of the semiconductor substrate 2.

Since the (100) and (111) planes of the semiconductor substrate 2 intersect at an angle of 54.7°, the normals N1 and N2 of the inclined surfaces 11a and 11b intersect with the normal N0 of the first surface 2a at an angle θ=54.7°. The V-shaped groove can also be formed by, for example, etching with an ion beam so that the angle θ is greater than 45°.

The two inclined surfaces 11a, 11b constituting the inclined portion 11 (V-shaped groove) are flat when formed by anisotropic etching. These inclined surfaces 11a, 11b are roughened by forming a microtexture 12 consisting of fine irregularities. The microtexture 12 is formed by sandblasting, for example, by spraying fine granular abrasive Ab from a nozzle Nz, as shown in FIG. 4.

For example, a semiconductor substrate 2 having a plurality of inclined portions 11 formed on the second surface 2b side corresponding to a plurality of light receiving portions 6 on the first surface 2a side of the semiconductor substrate 2 is subjected to sandblasting on the second surface 2b side along the inclined portions 11. As a result, a microtexture 12 is formed on each of the inclined surfaces 11a, 11b. When the microtexture 12 on the inclined portions 11 is formed, the microtexture 12 can also be formed on the second surface 2b of the semiconductor substrate 2.

The microtexture 12 acts to continuously change the refractive index between the semiconductor substrate 2 and its outside (air), reducing the reflection of light at the inclined surfaces 11a and 11b. After the sandblasting process, the semiconductor substrate 2 is cut with a dicing saw to separate the semiconductor light receiving elements 1. The end face of the cut semiconductor substrate 2 can be made into a rough surface with fine irregularities similar to the microtexture 12, depending on the cutting conditions including the size of the abrasive grains fixed to the dicing saw.

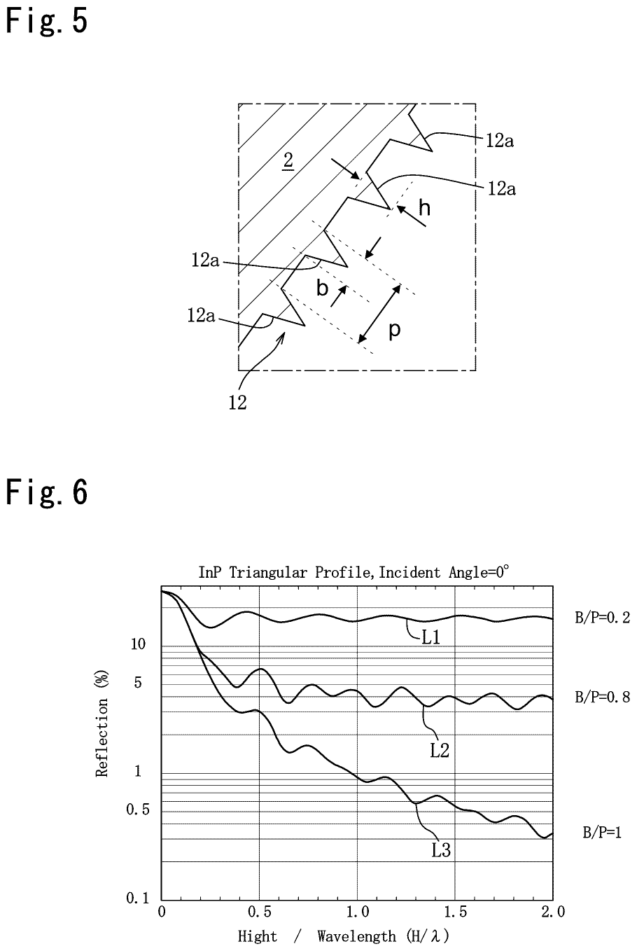

FIG. 5 is a cross-sectional model diagram of the microtexture 12. The microtexture 12 has a plurality of minute protrusions 12a formed by processing the semiconductor substrate 2. The cross section of the protrusions 12a is simplified to, for example, a triangular shape, the height of the protrusions 12a is h, the width of the base end of the protrusions 12a is b, and the arrangement pitch of the protrusions 12a is p, and the average values of these are the average height H, average width B, and average pitch P, respectively.

By appropriately selecting processing conditions such as the particle size and ejection speed of the abrasive Ab ejected in the sandblasting process, it is possible to adjust the size of the protrusions 12a formed on the inclined portion 11. Since the multiple fine protrusions 12a are formed in a V-shaped groove recessed into the semiconductor substrate 2, the multiple protrusions 12a are protected from, for example, collisions and abrasions with external objects and are less likely to be damaged, making the semiconductor light receiving element 1 easier to handle.

FIG. 6 shows the results of a simulation of the reflectance of the inclined surface 11a having the microtexture 12. The relationship between the reflectance and the ratio (H/λ) of the average height H of the multiple protrusions 12a to the wavelength λ of light traveling through the semiconductor substrate 2 is shown by curves L1 to L3 according to the density of the multiple protrusions 12a in the cross section of the inclined surface 11a. The density of the multiple protrusions 12a is represented by the ratio (B/P) of the average width B of the multiple protrusions 12a to the average pitch P of the multiple protrusions 12a. The wavelength λ of the light traveling through the semiconductor substrate 2 corresponds to the wavelength of the transmitted light that passes through the light absorption layer 4 of the light receiving section 6 and reaches the inclined section 11.

In the case of a flat inclined surface 11a without any protrusions 12a (average height H=0, i.e. H/λ=0), the reflectance is about 27%, but the reflectance tends to decrease as the ratio (H/λ) of the average height H of the multiple protrusions 12a to the wavelength λ increases. Also, the reflectance decreases as the density (B/P) of the multiple protrusions 12a increases. Note that while FIG. 6 shows the case where light is incident perpendicularly on the inclined surface 11a, the same tendency occurs even if the angle of incidence is changed.

When the ratio (H/λ) of the average height H of the plurality of protrusions 12a to the wavelength λ of light traveling through the semiconductor substrate 2 is 1 or more and the density (B/P) of the plurality of protrusions 12a is 0.8 (80%) or more, the reflectance can be reduced to 5% or less. Also, when the density (B/P) of the plurality of protrusions 12a is 1 (100%), the ratio (H/λ) of the average height H of the plurality of protrusions 12a to the wavelength λ of light traveling through the semiconductor substrate 2 is 1 or more and the reflectance can be reduced to 1% or less.

In order to reduce the reflectance in this manner, a microtexture 12 is formed on the inclined surfaces 11a and 11b, which has a plurality of protrusions 12a formed to have an average height H equal to or greater than the wavelength λ of the light traveling through the semiconductor substrate 2 and a density (B/P) of 80% or more.

When the refractive index of air is 1 for infrared light having a wavelength of, for example, 1600 nm in air, if the semiconductor substrate 2 is an n-InP substrate, the refractive index is about 3.2, so that H/λ can be made 1 or more by setting the average height H of the protrusions 12a to about 500 nm.

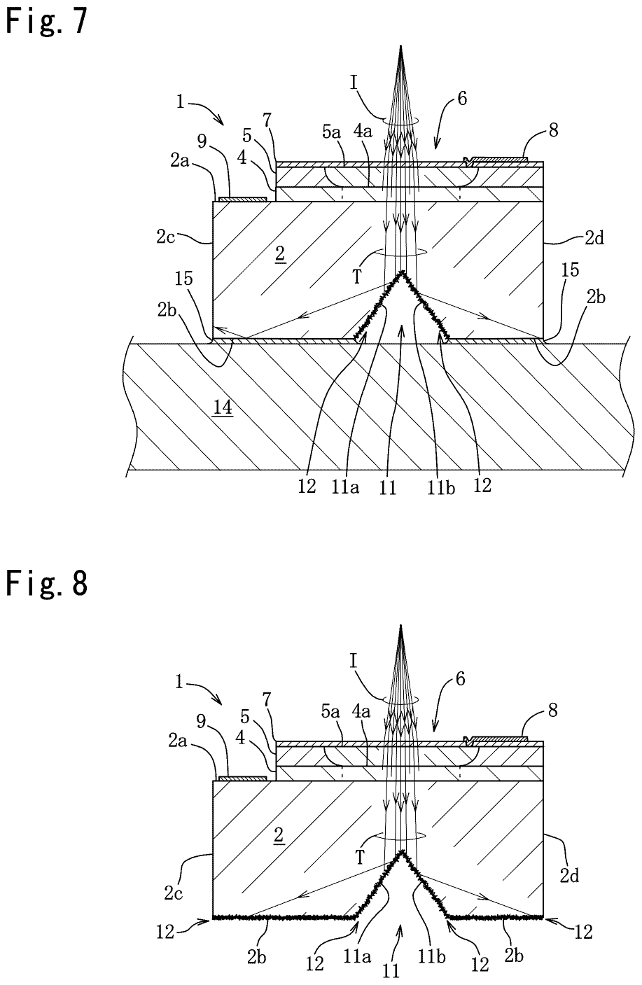

FIG. 7, in the semiconductor light receiving element 1, the second surface 2b side of the semiconductor substrate 2 is fixed to a mounting member 14, such as a substrate equipped with terminals, by an adhesive 15. Light is incident on the light receiving section 6 from the opposite side to the mounting member 14, i.e., the opposite side to the semiconductor substrate 2. Part of this incident light I is converted to a photocurrent in the light receiving section 6 and output, and the majority of the remaining light passes through the light absorbing layer 4 (light absorbing region 4a) of the light receiving section 6.

The transmitted light T that has passed through the light absorbing layer 4 of the light receiving section 6 reaches the inclined section 11, and most of the transmitted light T goes out of the semiconductor substrate 2 without being reflected from the inclined surfaces 11a and 11b on which the microtexture 12 is formed. Because the inclined section 11 is a V-shaped groove, even if the second surface 2b side of the semiconductor substrate 2 is fixed to the mounting member 14, the transmitted light T that has passed through the light absorbing layer 4 of the light receiving section 6 can be guided out of the semiconductor substrate 2. Note that the mounting member 14 preferably has a function of transmission, absorption, or anti-reflection, for example, so that the light that has passed through the semiconductor substrate 2 does not return to the inclined section 11.

In addition, since the inclined surfaces 11a and 11b of the inclined portion 11 are the (111) surface of the semiconductor substrate 2, a portion of the transmitted light T is reflected by the inclined portion 11 toward the second surface 2b of the semiconductor substrate 2. The light is then further reflected by the second surface 2b and exits from the end surfaces 2c and 2d to the outside of the semiconductor substrate 2. Therefore, most of the transmitted light T that reaches the inclined portion 11 exits to the outside of the semiconductor substrate 2, reducing the amount of the transmitted light T re-entering the light receiving unit 6. If the end surfaces 2c and 2d of the semiconductor substrate 2 are roughened, the reflection at the end surfaces 2c and 2d is reduced, and the amount of the transmitted light T re-entering the light receiving unit 6 is further reduced.

FIG. 8, when the microtexture 12 is also formed on the second surface 2b of the semiconductor substrate 2, most of the transmitted light T that reaches the second surface 2b goes out of the semiconductor substrate 2 without being reflected by the second surface 2b. Therefore, the transmitted light T that is reflected by the end faces 2c and 2d after being reflected by the second surface 2b of the semiconductor substrate 2 is reduced, so that the re-entry of the light to the light receiving unit 6 can be further reduced.

In the case of FIG. 8, it is preferable to fix an end face of the semiconductor substrate 2 other than, for example, end faces 2c and 2d (end faces parallel to the cross section of FIG. 8) to a mount member (not shown) with an adhesive. This prevents the reflection reducing function of the microtexture 12 formed on the second surface 2b of the semiconductor substrate 2 from being limited by, for example, an adhesive. Note that even if there is no microtexture 12 on the second surface 2b of the semiconductor substrate 2, the end face of the semiconductor substrate 2 can be fixed to a mount member.

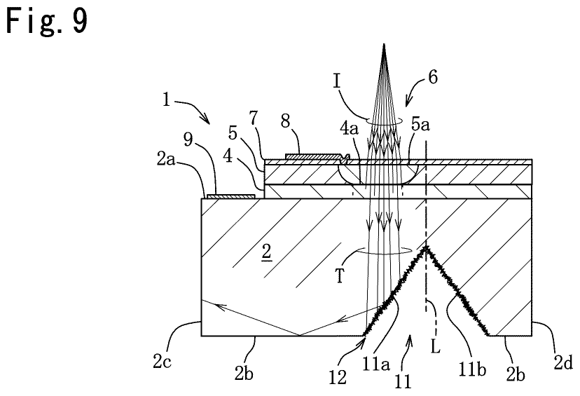

FIG. 9, the inclined portion 11 may be formed large so that the transmitted light T is received only by the inclined surface 11a on which the microtexture 12 is formed, for example. In this case as well, most of the transmitted light T that reaches the inclined portion 11 goes out of the semiconductor substrate 2 without being reflected, so that the re-entry of the transmitted light T into the light receiving portion 6 is reduced. By forming the light receiving portion 6, the anode electrode 8, and the cathode electrode 9 also on the inclined surface 11b side, forming the semiconductor light receiving element 1 symmetrically with respect to one V-shaped groove, and dividing it by the line L, it is possible to improve the manufacturing efficiency of the semiconductor light receiving element 1 having the roughened inclined portion 11.

The operation and effects of the semiconductor light receiving element 1 will now be described. The semiconductor light receiving element 1 includes a light receiving section 6 having a light absorbing layer 4 on the first surface 2a side of a semiconductor substrate 2 that is transparent to light in the infrared light region used in optical communications. Light is incident on this light receiving section 6 from the opposite side to the semiconductor substrate 2. The second surface 2b side of the semiconductor substrate 2 includes an inclined portion 11 that is inclined at a predetermined angle θ with respect to the first surface 2a of the semiconductor substrate 2 in a region where transmitted light T that has passed through the light absorbing layer 4 of the light receiving section 6 reaches.

Since the inclined portion 11 is formed with a rough surface having unevenness with a height equal to or greater than the wavelength λ of the transmitted light T, most of the transmitted light T that reaches the inclined portion 11 goes out of the semiconductor substrate 2 without being reflected. Moreover, since the inclined portion 11 is inclined at a predetermined angle θ with respect to the first surface 2a of the semiconductor substrate 2, it is possible to prevent the light of the transmitted light T that is reflected by the inclined portion 11 from being reflected toward the light receiving portion 6. Therefore, it is possible to reduce the re-entry of the transmitted light T that has passed through the light absorption layer 4 of the light receiving portion 6 into the light receiving portion 6, thereby shortening the fall time of the semiconductor light receiving element 1.

The inclined portion 11 is formed by a V-shaped groove recessed from the second surface 2b side of the semiconductor substrate 2 toward the first surface 2a side. The rough surface formed in this V-shaped groove protects the semiconductor light receiving element 1 from damage caused by collision or rubbing with an external object. This makes it easier to handle the semiconductor light receiving element 1. Even if the second surface 2b side of the semiconductor light receiving element 1 is fixed to the mounting member 14, the transmitted light T that has passed through the light absorption layer 4 of the light receiving portion 6 can be guided to the outside of the semiconductor substrate 2, reducing re-entry into the light receiving portion 6.

The first surface 2a of the semiconductor substrate 2 is the (100) surface of the semiconductor substrate 2, and the inclined portion 11 is formed on the (111) surface of the semiconductor substrate 2. Therefore, the predetermined angle θ of the inclined portion 11 with respect to the first surface 2a of the semiconductor substrate 2 is determined so that the transmitted light T reflected by the inclined portion 11 is directed toward the second surface 2b of the semiconductor substrate 2. Therefore, it is possible to prevent the transmitted light T that has passed through the light absorption layer 4 of the light receiving portion 6 from being reflected by the inclined portion 11 so as to return to the light receiving portion 6.

When a rough surface having projections and recesses with a depth equal to or greater than the wavelength λ of the transmitted light T that has passed through the light absorbing layer 4 of the light receiving section 6 is formed on the second surface 2b of the semiconductor substrate 2, it is possible to reduce reflection at the second surface 2b when a part of the transmitted light T is reflected by the inclined portion 11 and reaches the second surface 2b. Therefore, it is possible to further reduce the re-entry of the transmitted light T that has passed through the light absorbing layer 4 of the light receiving section 6 into the light receiving section 6.

The light receiving section 6 may be, for example, an avalanche photodiode equipped with a multiplication layer, or a photodiode formed of a material and in a different shape from the above. In addition, a person skilled in the art can implement the present invention in a form in which various modifications are added to the above embodiment without departing from the present invention, and the present invention also includes such modifications.

1. A semiconductor light receiving element including a light receiving portion having a light absorption layer on a first surface side of a semiconductor substrate transparent to light having a wavelength in an infrared region for optical communication; wherein a second surface side of the semiconductor substrate opposite to the first surface includes an inclined portion inclined at a predetermined angle with respect to the first surface in a region where transmitted light that is transmitted through the light absorption layer out of incident light that is incident on the light receiving portion from an opposite side to the semiconductor substrate reaches the second surface side of the semiconductor substrate, and
a rough surface having irregularities with a height equal to or greater than the wavelength of the transmitted light is formed on the inclined portion.

2. The semiconductor light receiving element according to claim 1, wherein the inclined portion is formed by a V-shaped groove recessed into the semiconductor substrate from the second surface toward the first surface.

3. The semiconductor light receiving element according to claim 1, wherein the first surface of the semiconductor substrate is a (100) surface of the semiconductor substrate, and the inclined portion is formed on a (111) surface of the semiconductor substrate.

4. The semiconductor light receiving element according to claim 1, wherein the second surface of the semiconductor substrate is formed with a rough surface having irregularities with a height equal to or greater than the wavelength of the transmitted light.
